(19) United States
(12) Patent Application Publication
(10) Pub. No.: US 2017/0278804 A1
(43) Pub. Date: Sep. 28, 2017

(54) ELECTRONIC CIRCUIT PACKAGE

(71) Applicant: TDK Corporation, Tokyo (JP)

(72) Inventors: KENICHI KAWABATA, TOKYO (JP); Toshio HAYAKAWA, TOKYO (JP); Toshiro OKUBO, TOKYO (JP)

(73) Assignee: TDK Corporation, Tokyo (JP)

(21) Appl. No.: 15/351,758

(22) Filed: Nov. 15, 2016

(30) Foreign Application Priority Data
Mar. 23, 2016 (JP) 2016-058729

(51) Int. Cl. H01L 23/552; H01L 21/56; H01L 23/29; H01L 23/498; H01L 23/00; H01L 23/31

(52) U.S. Cl. CPC H01L 23/552; H01L 23/564; H01L 23/3135; H01L 23/29; H01L 23/49805; H01L 21/561

(57) ABSTRACT

Disclosed herein is an electronic circuit package includes: a substrate having a power supply pattern; an electronic component mounted on a surface of the substrate; a mold resin covering the surface of the substrate so as to embed therein the electronic component; a magnetic film formed so as to contact at least a top surface of the mold resin; and a metal film electrically connected to the power supply pattern and covering the mold resin through the magnetic film.

### BACKGROUND OF THE INVENTION

Field of the Invention

The present invention relates to an electronic circuit package and, more particularly, to an electronic circuit package provided with a composite shielding function having both an electromagnetic shielding function and a magnetic shielding function.

Description of Related Art

In recent years, an electronic device such as a smartphone is equipped with a high-performance radio communication circuit and a high-performance digital chip, and an operating frequency of a semiconductor IC used therein tends to increase. Further, adoption of an SIP (System-In Package) having a 2.5D or 3D structure, in which a plurality of semiconductor ICs are connected by a shortest wiring, is accelerated, and modularization of a power supply system is expected to accelerate. Further, an electronic circuit module having a large number of modulated electronic components (collective term of components, such as passive components (an inductor, a capacitor, a resistor, a filter, etc.), active components (a transistor, a diode, etc.), integrated circuit components (an semiconductor IC, etc.) and other components required for electronic circuit configuration) is expected to become more and more popular, and an electronic circuit package which is a collective term for the above SIP, electronic circuit module, and the like tends to be mounted in high density along with sophistication, miniaturization, and thinning of an electronic device such as a smartphone. However, this tendency poses a problem of malfunction and radio disturbance due to noise. The problem of malfunction and radio disturbance is difficult to be solved by conventional noise countermeasure techniques. Thus, recently, self-shielding of the electronic circuit package has become accelerated, and an electromagnetic shielding using a conductive paste or a plating or sputtering method has been proposed and put into practical use, and higher shielding characteristics are required in the future.

In order to realize the higher shielding characteristics, a composite shielding structure is proposed in recent years. The composite shielding structure has both an electromagnetic shielding function and a magnetic shielding function. In order to realize the composite shielding structure, it is necessary to form, in an electronic circuit package, an electromagnetic shielding by a conductive film (metal film) and a magnetic shielding by a magnetic film.

For example, an electronic circuit module described in Japanese Patent Application Laid-Open No. 2010-087058 has a configuration in which a metal film and a magnetic layer are laminated in this order on a surface of a mold resin. Further, a semiconductor package described in U.S. Patent Publication No. 2011/0304015 has a configuration in which a shield case (shield can) obtained by laminating a magnetic layer and a metal film is bonded to a mold resin by an adhesive.

However, study of the present inventors reveals the following problems. That is, with the configuration like Japanese Patent Application Laid-Open No. 2010-087058 in which a metal film and a magnetic layer are laminated in this order on a surface of a mold resin, a sufficient shield effect cannot be obtained as an electronic circuit package for mobile communication device required to have a higher shield effect in the future. On the other hand, the configuration like U.S. Patent Publication No. 2011/0304015 in which the shield case is bonded by an adhesive is disadvantageous for height reduction and makes it difficult to connect the metal film to a grand pattern on a substrate.

### SUMMARY

The object of the present invention is therefore to provide an electronic circuit package capable of achieving both a high composite-shield effect and height reduction.

An electronic circuit package according to the present invention includes a substrate having a power supply pattern; an electronic component mounted on a surface of the substrate; a mold resin covering the surface of the substrate so as to embed therein the electronic component; a magnetic film formed so as to contact at least a top surface of the mold resin; and a metal film connected to the power supply pattern and covering the mold resin through the magnetic film.

According to the present invention, the magnetic film and metal film are formed on the top surface of the mold resin in this order, so that high composite-shield characteristics can be obtained. In addition, the magnetic film is directly formed on the top surface of the mold resin without intervention of an adhesive or the like. This is advantageous for height reduction.

In the present invention, the magnetic film preferably further contacts the side surface of the mold resin. With this configuration, the composite-shield characteristics can be enhanced in the side surface direction. In this case, the magnetic film preferably covers a part of the side surface of the substrate.

In the present invention, the magnetic film may be a film formed of a composite magnetic material in which magnetic fillers are dispersed in a thermosetting resin material, or a thin film, a foil or a bulk sheet formed of a soft magnetic material or a ferrite. When the film formed of a composite magnetic material is used, the magnetic filler is preferably formed of a ferrite or a soft magnetic metal, and a surface of the filler is preferably insulation-coated.

Preferably, in the present invention, the metal film is mainly composed of at least one metal selected from a group consisting of Au, Ag, Cu, and Al, and more preferably, the surface of the metal film is covered with an antioxidant film.

In the present invention, it is preferable that the power supply pattern is exposed to a side surface of the substrate and that the metal film contacts the exposed power supply pattern. With this configuration, it is possible to easily and reliably connect the metal film to the power supply pattern.

As described above, according to the present invention, it is possible to realize both high composite shielding effect and reduction in height.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view illustrating a configuration of an electronic circuit package according to a first embodiment of the present invention;

FIG. 2 is a cross-sectional view illustrating a configuration of an electronic circuit package according to a modification of the first embodiment;

FIGS. 3 to 6 are process views for explaining a manufacturing method for the electronic circuit package shown in FIG. 1;

FIG. 7 is a cross-sectional view illustrating a configuration of an electronic circuit package according to a second embodiment of the present invention;

FIG. 8 is a cross-sectional view illustrating a configuration of an electronic circuit package according to a modification of the second embodiment;

FIGS. 9 and 10 are process views for explaining a manufacturing method for the electronic circuit package shown in FIG. 7;

FIG. 11 is a cross-sectional view illustrating a configuration of an electronic circuit package according to a third embodiment of the present invention;

FIG. 12 is a cross-sectional view illustrating a configuration of an electronic circuit package according to a first modification of the third embodiment;

FIG. 13 is a cross-sectional view illustrating a configuration of an electronic circuit package according to a second modification of the third embodiment;

FIG. 14 is a cross-sectional view illustrating a configuration of an electronic circuit package according to a third modification of the third embodiment;

FIG. 15 is a cross-sectional view illustrating a configuration of an electronic circuit package according to a fourth modification of the third embodiment;

FIGS. 16 to 18 are process views for explaining a manufacturing method for the electronic circuit package shown in FIG. 11;

FIG. 19 is a cross-sectional view illustrating a configuration of an electronic circuit package according to a fourth embodiment of the present invention;

FIG. 20 is a cross-sectional view illustrating a configuration of an electronic circuit package according to a modification of the fourth embodiment;

FIGS. 21 and 22 are process views for explaining a manufacturing method for the electronic circuit package shown in FIG. 19;

FIG. 23 is a cross-sectional view illustrating a configuration of an electronic circuit package according to a fifth embodiment of the present invention;

FIG. 24 is a cross-sectional view illustrating a configuration of an electronic circuit package according to a first modification of the fifth embodiment;

FIG. 25 is a cross-sectional view illustrating a configuration of an electronic circuit package according to a second modification of the fifth embodiment; and

FIG. 26 is a cross-sectional view illustrating a configuration of an electronic circuit package according to a third modification of the fifth embodiment.

### DETAILED DESCRIPTION OF THE EMBODIMENTS

Preferred embodiments of the present invention will be explained below in detail with reference to the accompanying drawings.

### First Embodiment

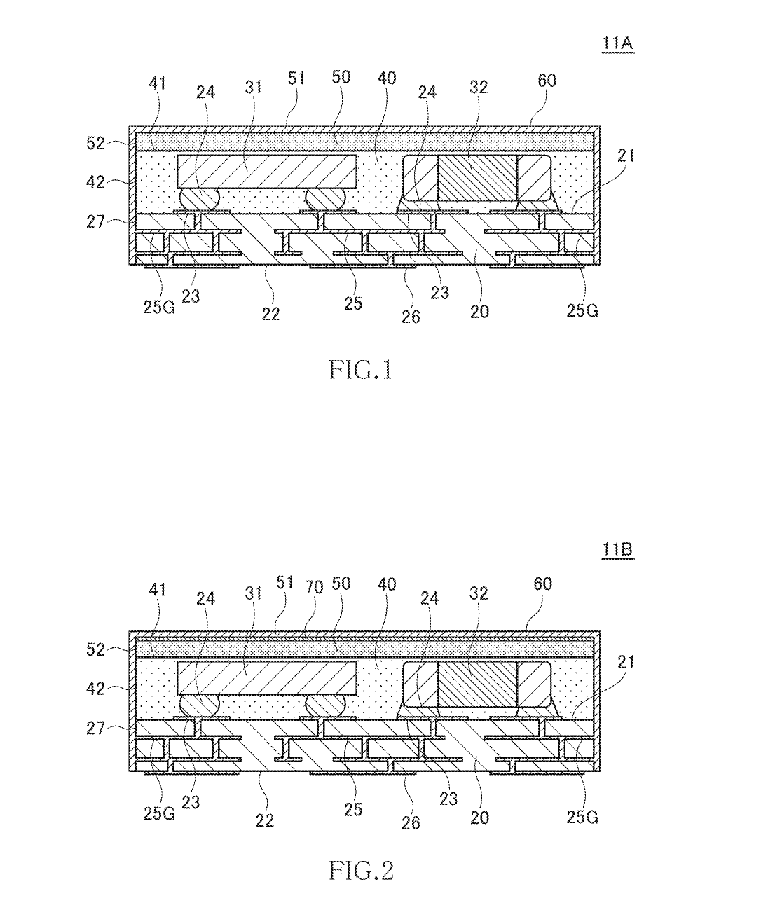

FIG. 1 is a cross-sectional view illustrating a configuration of an electronic circuit package 11A according to the first embodiment of the present invention.

As illustrated in FIG. 1, the electronic circuit package 11A according to the present embodiment includes a substrate 20, a plurality of electronic components 31 and 32 mounted on the substrate 20, a mold resin 40 covering a front surface 21 of the substrate 20 so as to embed the electronic components 31 and 32, a magnetic film 50 covering the mold resin 40, and a metal film 60 covering the mold resin 40 and the magnetic film.

Although the type of the electronic circuit package 11A according to the present embodiment is not especially limited, examples thereof include a high-frequency module handling a high-frequency signal, a power supply module performing power supply control, an SIP (System-In-Package) having a 2.5D structure or a 3D structure, and a semiconductor package for radio communication or digital circuit. Although only two electronic components 31 and 32 are illustrated in FIG. 1, more electronic components are incorporated actually.

The substrate 20 has a double-sided and multilayer wiring structure in which a large number of wirings are embedded therein and may be any type of substrate including: a thermosetting resin based organic substrate such as an FR-4, an FR-5, a BT, a cyanate ester substrate, a phenol substrate, or an imide substrate; a thermoplastic resin based organic substrate such as a liquid crystal polymer; an LTCC substrate; an HTCC substrate; and a flexible substrate. In the present embodiment, the substrate 20 has a four-layer structure including wiring layers formed on the front surface 21 and a back surface 22 and two wiring layers embedded therein. Land patterns 23 are an internal electrode for connecting to the electronic components 31 and 32. The land patterns 23 and each of the electronic components 31 and 32 are electrically and mechanically connected to each other through a respective solder 24 (or a conductive paste). For example, the electronic component 31 is a semiconductor chip such as a controller, and electronic component 32 is a passive component such as a capacitor or a coil. Some electronic components (e.g., thinned semiconductor chip) may be embedded in the substrate 20.

The land patterns 23 are connected to external terminals 26 formed on the back surface 22 of the substrate 20 through internal wirings 25 formed inside the substrate 20. Upon actual use, the electronic circuit package 11A is mounted on an unillustrated mother board, and land patterns on the mother board and the external terminals 26 of the electronic circuit package 11A are electrically connected. A material for a conductor forming the land patterns 23, internal wirings 25, and external terminals 26 may be a metal such as copper, silver, gold, nickel, chrome, aluminum, palladium, indium, or a metal alloy thereof or may be a conductive material using resin or glass as a binder; however, when the substrate 20 is an organic substrate or a flexible substrate, copper or silver is preferably used in terms of cost and conductivity. The above conductive materials may be formed by using various methods such as printing, plating, foil lamination, sputtering, vapor deposition, and inkjet.

Out of the internal wirings 25 illustrated in FIG. 1, internal wirings 25G are power supply patterns. The power supply patterns 25G are typically ground patterns to which a ground potential is to be applied; however, it is not limited to the ground patterns as long as the power supply patterns 25G are a pattern to which a fixed potential is to be applied.

The mold resin 40 covers the surface 21 of the substrate 20 so as to embed therein the electronic components 31 and 32. In the present embodiment, a side surface 42 of the mold resin 40 and a side surface 27 of the substrate 20 form the same plane. As a material for the mold resin 40, a material based on a thermosetting material or a thermoplastic material and blended with fillers for adjusting a thermal expansion coefficient can be used.

A top surface 41 of the mold resin 40 is covered with the magnetic film 50, and the top surface 41 and magnetic film 50 directly contact each other without intervention of an adhesive or the like. The magnetic film 50 may be a film formed of a composite magnetic material in which magnetic fillers are dispersed in a thermosetting resin material, a thin film formed of a soft magnetic material or a ferrite, or a foil or a bulk sheet and serves as a magnetic shield.

When the film formed of a composite magnetic material is selected as the magnetic film 50, an epoxy resin, a phenol resin, a silicone resin, a diallyl phthalate resin, a polyimide resin, an urethane resin, and the like may be used as the thermosetting resin material, and the magnetic film 50 can be formed by using a thick-film formation method such as a printing method, a molding method, a slit nozzle coating method, a spray method, a dispensing method, an injection method, a transfer method, a compression molding method, or a lamination method using an uncured sheet-like resin. Using the thermosetting resin material can increase reliability (heat resistance, insulation performance, impact resistance, falling resistance) required for electronic circuit packages.

As the magnetic filler, a ferrite or a soft magnetic metal is preferably used, and a soft magnetic metal having a high bulk permeability is more preferably used. As the ferrite or soft magnetic metal, one or two or more metals selected from a group consisting of Fe, Ni, Zn, Mn, Co, Cr, Mg, Al, and Si and oxides thereof may be used. Specific examples include a ferrite (Ni—Zn ferrite, Mn—Zn ferrite, Ni—Cu—Zn ferrite, etc.), a permalloy (Fe—Ni alloy), a super permalloy (Fe—Ni—Mo alloy), a sendust (Fe—Si—Al alloy), an Fe—Si alloy, an Fe—Co alloy, an Fe—Cr alloy, an Fe—Cr—Si alloy, and Fe. The shape of the magnetic filler is not especially limited; however, it may be formed into a spherical shape for a high filling level, and fillers of a plurality of particle sizes may be blended for a densest filling structure. In order to maximize a shield effect by a permeability real component and a thermal conversion effect by a loss of a permeability imaginary component, the magnetic filler is more preferably formed by adding flat powder having an aspect ratio of 5 or more.

Preferably, the surface of the magnetic filler is insulation-coated by an oxide of a metal such as Si, Al, Ti, or Mg, or an organic material for enhancing fluidity, adhesion, and insulation performance. The insulation coating may be formed by coating a thermosetting material on the surface of the magnetic filler. Alternatively, an oxide film may be formed as the insulation coating by dehydration reaction of a metal alkoxide, and in this case, formation of a silicon oxide coating film is most preferable. More preferably, organic functional coupling treatment is applied to the formed coating film.

The composite magnetic material can be formed on the top surface 41 of the mold resin using a known method such as a printing method, a molding method, a slit nozzle coating method, a spray method, a dispensing method, or a lamination method using an uncured sheet-like resin.

When the thin film formed of a soft magnetic material or a ferrite is selected as the magnetic film 50, one or two or more metals selected from a group consisting of Fe, Ni, Zn, Mn, Co, Cr, Mg, Al, and Si and oxides thereof may be used. In this case, the magnetic film 50 can be formed on the top surface 41 of the mold resin 40 by using a plating method, a spray method, an AD method, and a thermal spraying method, as well as a thin-film formation method such as a sputtering method or a vapor-deposition method. In this case, the material for the magnetic film 50 may be appropriately selected from a required permeability and frequency; however, in order to enhance a shield effect on a lower frequency side (kHz to 100 MHz), an Fe—Co alloy, an Fe—Ni alloy, an Fe—Al alloy, or an Fe—Si alloy is most preferably used. On the other hand, in order to enhance a shield effect on a higher frequency side (50 to several hundreds of MHz), a ferrite film formed of NiZn, MnZn, or NiCuZn, or Fe is most preferably used.

When a foil or a bulk sheet is used as the magnetic film 50, the foil or bulk sheet is previously set in a die for forming the mold resin 40. This allows the magnetic film 50 to be directly formed on the top surface 41 of the mold resin 40.

The top and side surfaces 51 and 52 of the magnetic film 50, the top and side surfaces 41 and 42 of the mold resin 40 and the side surface 27 of the substrate 20 are covered with the metal film 60. The metal film 60 serves as an electromagnetic shielding and is preferably mainly composed of at least one metal selected from a group consisting of Au, Ag, Cu, and Al. The metal film 60 preferably has a resistance as low as possible and most preferably uses Cu in terms of cost. An outer surface of the metal film 60 is preferably covered with an anticorrosive metal such as SUS, Ni, Cr, Ti, or brass or an antioxidant film made of a resin such as an epoxy resin, a phenol resin, an imide resin, an urethane resin, or a silicone resin. The reason for this is that the metal film 60 undergoes oxidative deterioration by an external environment such as heat or humidity; and, therefore, the aforementioned treatment is preferable to suppress and prevent the oxidative deterioration. A formation method for the metal film 60 may be appropriately selected from known methods, such as a sputtering method, a vapor-deposition method, an electroless plating method, an electrolytic plating method. Before formation of the metal film 60, pretreatment for enhancing adhesion, such as plasma treatment, coupling treatment, blast treatment, or etching treatment, may be performed. As a base of the metal film 60, a high adhesion metal film such as a titanium film, a chromium film, or an SUS film may be formed thinly in advance.

As illustrated in FIG. 1, the power supply patterns 25G are exposed to the side surfaces 27 of the substrate 20. The metal film 60 covers the side surfaces 27 of the substrate 20 and is thereby electrically connected to the power supply pattern 25G.

Although not especially limited, it is desirable that a resistance value at an interface between the metal film 60 and the magnetic film 50 is equal to or larger than 10⁶Ω. According to this configuration, an eddy current generated when electromagnetic wave noise enters the metal film 60 hardly flows in the magnetic film 50, which can prevent deterioration in the magnetic characteristics of the magnetic film 50 due to inflow of the eddy current. The resistance value at the interface between the metal film 60 and the magnetic film 50 refers to a surface resistance of the magnetic film 50 when the metal film 60 and magnetic film 50 directly contact each other and to a surface resistance of an insulating film when the insulating film is present between the metal film 60 and the magnetic film 50.

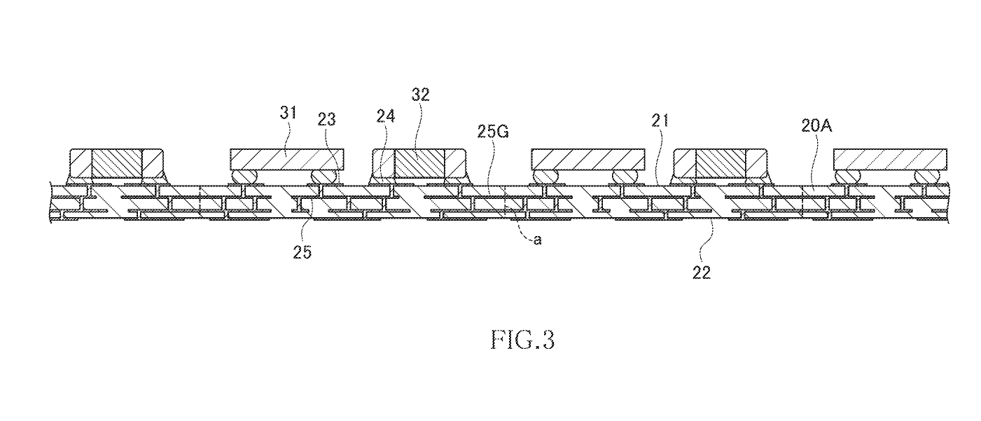

In order to make a resistance value at an interface between the metal film 60 and the magnetic film 50 equal to or higher than 10⁶Ω, a material having a sufficiently high surface resistance is used as the material for the magnetic film 50 or a thin insulating material is formed on the top surface 51 of the magnetic film 50. FIG. 2 is a cross-sectional view illustrating a configuration of an electronic circuit package 11B according to a modification. The electronic circuit package 11B of FIG. 2 differs from the electronic circuit package 11A of FIG. 1 in that a thin insulating film 70 is interposed between the magnetic film 50 and the metal film 60. By interposing the insulating film 70, it is possible to make a resistance value at an interface between the metal film 60 and the magnetic film 50 equal to or higher than 10⁶Ω even when a material having a comparatively low resistance value is used as the material for the magnetic film 50, thereby making it possible to prevent deterioration in magnetic characteristics due to an eddy current.

As described above, in the electronic circuit package 11A (and 11B) according to the present embodiment, the magnetic film 50 and metal film 60 are laminated in this order on the top surface 41 of the mold resin 40. With this configuration, as compared with a case where the magnetic film 50 and metal film 60 are laminated in the reverse order, electromagnetic noise radiated from the electronic components 31 and 32 can be shielded more effectively. This is because the electromagnetic wave noise radiated from the electronic components 31 and 32 is partially absorbed when it passes through the magnetic film 50, and the remaining electromagnetic wave noise that has not been absorbed is partially reflected by the metal film 60 and passes through the magnetic film 50 once again. In this manner, the magnetic film 50 acts on the incident electromagnetic wave noise twice, thereby effectively shielding the electromagnetic wave noise radiated from the electronic components 31 and 32.

Further, in the electronic circuit package 11A (and 11B) according to the present embodiment, the magnetic film 50 is directly formed on the top surface 41 of the mold resin 40 without intervention of an adhesive or the like. This is advantageous for height reduction. In addition, in the present embodiment, the magnetic film 50 is formed only on the top surface 41 of the mold resin 40, so that the metal film 60 can be easily connected to the power supply pattern 25G.

The following describes a manufacturing method for the electronic circuit package 11A according to the present embodiment.

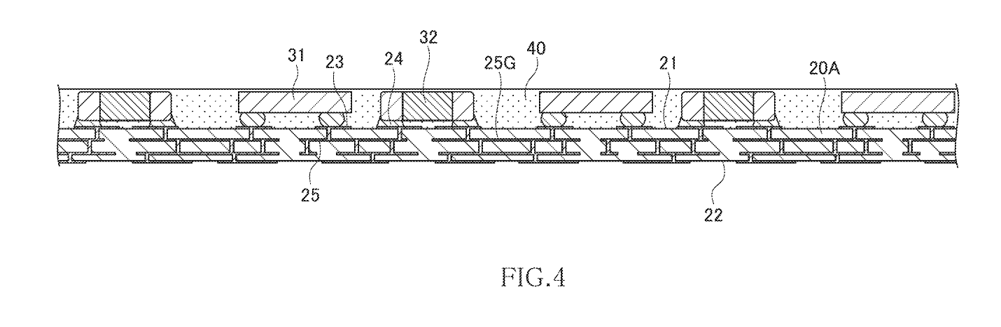

FIGS. 3 to 6 are process views for explaining a manufacturing method for the electronic circuit package 11A.

As illustrated in FIG. 3, an assembly substrate 20A having a multilayer wiring structure is prepared. A plurality of the land patterns 23 are formed on the front surface 21 of the assembly substrate 20A, and a plurality of the external terminals 26 are formed on the back surface 22 of the assembly substrate 20A. Further, a plurality of the internal wirings 25 including the power supply patterns 25G are formed in an inner layer of the assembly substrate 20A. A dashed line a in FIG. 3 denotes apart to be cut in a subsequent dicing process. As illustrated in FIG. 3, the power supply patterns 25G are provided at a position overlapping the dashed line a in a plan view.

Then, as illustrated in FIG. 3, the plurality of electronic components 31 and 32 are mounted on the front surface 21 of the assembly substrate 20A so as to be connected to the land patterns 23. Specifically, the solder 24 is provided on the land pattern 23, followed by mounting of the electronic components 31 and 32 and by reflowing, whereby the electronic components 31 and 32 are connected to the land patterns 23.

Then, as illustrated in FIG. 4, the front surface 21 of the assembly substrate 20A is covered with the mold resin 40 so as to embed the electronic components 31 and 32 in the mold resin 40. Examples of the formation method for the mold resin 40 may include, transfer molding, compression molding, injection molding, cast molding, vacuum cast molding, dispense molding, and molding using a slit nozzle.

Then, as illustrated in FIG. 5, the magnetic film 50 is directly formed on the top surface 41 of the mold resin 40. In this case, in order to enhance adhesion between the mold resin 40 and magnetic film 50, the top surface 41 of the mold resin 40 may be subjected to blast treatment or etching treatment to form a physical unevenness thereon, subjected to surface modification by plasma or short-wavelength UV irradiation, or subjected to organic functional coupling treatment.

When the film formed of a composite magnetic material is used as the magnetic film 50, a thick-film formation method such as a printing method, a molding method, a slit nozzle coating method, a spray method, a dispensing method, an injection method, a transfer method, a compression molding method, or a lamination method using an uncured sheet-like resin can be used. When the magnetic film 50 is formed by using the printing method, slit nozzle method, spraying method, or dispensing method, the viscosity of the composite magnetic material is preferably controlled as needed. The viscosity control may be made by diluting the composite magnetic material with one or two or more solvents having a boiling point of 50° C. to 300° C. The thermosetting material mainly consists of a main agent, a curing agent, and a curing accelerator; however, two or more kinds of main agent or curing agent may be blended according to required characteristics. Further, two or more kinds of solvents may be mixed: a coupling agent for enhancing adhesion and fluidity, a fire retardant for flame retardancy, a dye and a pigment for coloration, a non-reactive resin material for imparting flexibility, and a non-magnetic filler for adjusting a thermal expansion coefficient may be blended. The materials may be kneaded or dispersed by a known means such as a kneader, a mixer, a vacuum defoaming stirring machine, or a three-roll mill.

When the thin film formed of a soft magnetic material or a ferrite is used as the magnetic film 50, a plating method, a spray method, an AD method, and a thermal spraying method, as well as a thin-film formation method such as a sputtering method or a vapor-deposition method may be used. When a foil or a bulk sheet is used as the magnetic film 50, the foil or bulk sheet is previously set in a die for forming the mold resin 40. This allows the magnetic film 50 to be directly formed on the top surface 41 of the mold resin 40.

When the insulating film 70 is interposed between the magnetic film 50 and the metal film 60 as in the modification illustrated in FIG. 2, after formation of the magnetic film 50, an insulating material such as a thermosetting material, a heat-resistant thermoplastic material, an Si oxide, a low-melting point glass may be thinly formed on the top surface 51 of the magnetic film 50.

Then, as illustrated in FIG. 6, the assembly substrate 20A is cut along the dashed line a to divide the assembly substrate 20A into individual substrates 20. In the present embodiment, the power supply patterns 25G pass the dashed line a as a dicing position. Thus, when the assembly substrate 20A is cut along the dashed line a, the power supply patterns 25G are exposed from the side surface 27 of the substrate 20.

Then, the metal film 60 is formed so as to cover the top and side surfaces 51 and 52 of the magnetic film 50, the top and side surfaces 41 and 42 of the mold resin 40, and side surface 27 of the substrate 20, whereby the electronic circuit package 11A according to the present embodiment is completed. Examples of a formation method for the metal film 60 may include a sputtering method, a vapor-deposition method, an electroless plating method, and an electrolytic plating method. Before formation of the metal film 60, pretreatment for enhancing adhesion, such as plasma treatment, coupling treatment, blast treatment, or etching treatment, may be performed. As a base of the metal film 60, a high adhesion metal film such as a titanium film or a chromium film may be formed thinly in advance.

As described above, according to the manufacturing method for the electronic circuit package 11A of the present embodiment, the magnetic film 50 is directly formed on the top surface 41 of the mold resin 40, so that there is no need to use an adhesive or the like, thus being advantageous for height reduction. In addition, the power supply pattern 25G is exposed by cutting the assembly substrate 20A, so that the metal film 60 can be easily and reliably connected to the power supply pattern 25G.

### Second Embodiment

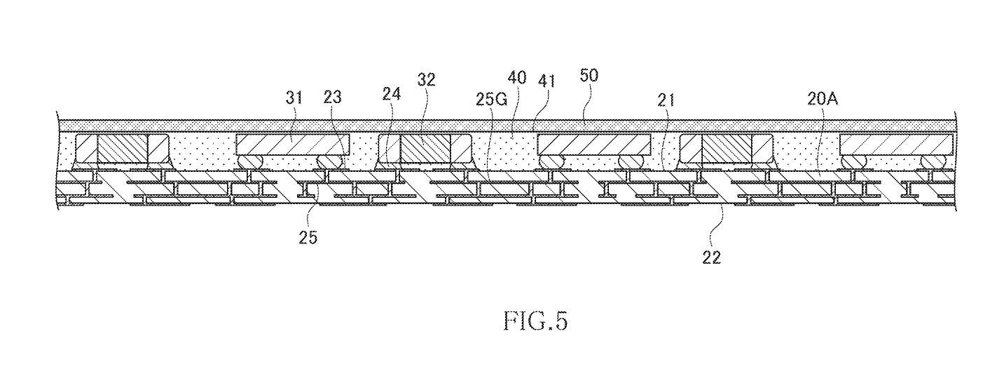

FIG. 7 is a cross-sectional view illustrating a configuration of an electronic circuit package 12A according to the second embodiment of the present invention.

As illustrated in FIG. 7, an electronic circuit package 12A according to the present embodiment is the same as the electronic circuit package 11A according to the first embodiment illustrated in FIG. 1 except for shapes of the substrate 20 and metal film 60. Thus, in FIG. 7, the same reference numerals are given to the same elements as in FIG. 1, and repetitive descriptions will be omitted.

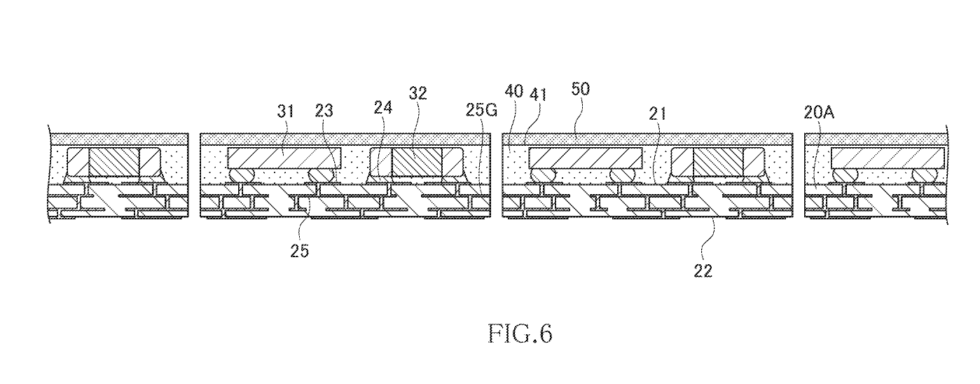

In the present embodiment, the side surface 27 of the substrate 20 is formed stepwise. Specifically, a side surface lower portion 27b protrudes from a side surface upper portion 27a. The metal film 60 is not formed over the entire side surface of the substrate 20 but formed so as to cover the side surface upper portion 27a and a step portion 27c. That is, the side surface lower portion 27b is not covered with the metal film 60. Also in the present embodiment, the power supply patterns 25G are exposed from the side surface upper portion 27a of the substrate 20, so that the metal film 60 is connected to the power supply patterns 25G at the exposed portion. When a material having relatively low resistance value is used as the magnetic film 50, it is desirable that the thin insulating film 70 interposed between the magnetic film 50 and the metal film 60 is used as in an electronic circuit package 12B according to a modification illustrated in FIG. 8.

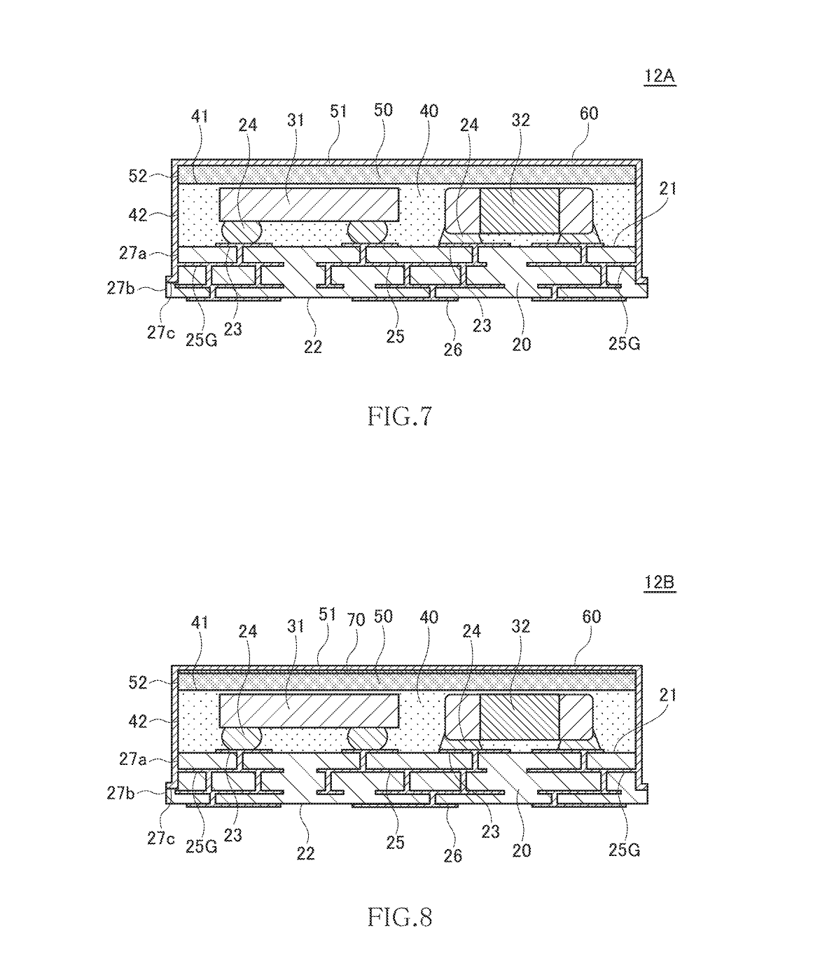

FIGS. 9 and 10 are process views for explaining a manufacturing method for the electronic circuit package 12A.

First, the magnetic film 50 is formed on the top surface 41 of the mold resin 40 by using the method described in FIGS. 3 to 5. Then, as illustrated in FIG. 9, a groove 43 is formed along the dashed line a denoting the dicing position. The groove 43 is formed so as to completely cut the mold resin 40 and so as not to completely cut the assembly substrate 20A. As a result, the side surface 42 of the mold resin 40 and side surface upper portion 27a and step portion 27c of the substrate 20 are exposed inside the groove 43. A depth of the groove 43 is set so as to allow at least the power supply patterns 25G to be exposed from the side surface upper portion 27a. When the insulating film 70 is interposed between the magnetic film 50 and the metal film 60 as in the modification illustrated in FIG. 8, an insulating material such as a thermosetting material, a heat-resistant thermoplastic material, an Si oxide, a low-melting point glass may be thinly formed on the top surface 51 of the magnetic film 50 before forming the groove 43.

Then, as illustrated in FIG. 10, the metal film 60 is formed by using a sputtering method, a vapor-deposition method, an electroless plating method, an electrolytic plating method, or the like. As a result, the top surface 51 of the magnetic film 50 and inside of the groove 43 are covered with the metal film 60. At this time, the power supply patterns 25G exposed to the side surface upper portion 27a of the substrate 20 are connected to the metal film 60.

Then, the assembly substrate 20A is cut along the dashed line a to divide the assembly substrate 20A into individual substrates 20, whereby the electronic circuit package 12A according to the present embodiment is completed.

As described above, according to the manufacturing method for the electronic circuit package 12A of the present embodiment, formation of the groove 43 allows the metal film 60 to be formed before dividing the assembly substrate 20A into individual substrates 20, thereby forming the metal film 60 easily and reliably.

### Third Embodiment

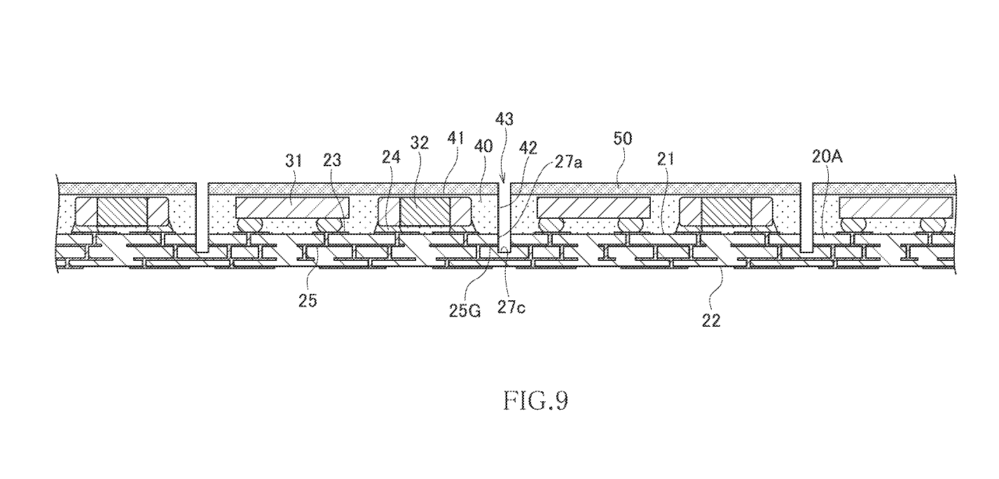

FIG. 11 is a cross-sectional view illustrating a configuration of an electronic circuit package 13A according to the third embodiment of the present invention.

As illustrated in FIG. 11, the electronic circuit package 13A according to the present embodiment differs from the electronic circuit package 11A of FIG. 1 according to the first embodiment in that the magnetic film 50 covers not only the top surface 41 of the mold resin 40, but also the side surface 42. Other configurations are the same as those of the electronic circuit package 11A according to the first embodiment. Thus, in FIG. 11, the same reference numerals are given to the same elements as in FIG. 1, and repeated descriptions will be omitted.

In the present embodiment, the side surface 42 of the mold resin 40 is fully covered with the magnetic film 50, and thus, a part where the mold resin 40 and metal film 60 contact each other does not substantially exist. With this configuration, a composite-shield effect in the side surface of the mold resin 40 can be enhanced. In particular, electromagnetic noise radiated in a side surface direction of the mold resin 40 is effectively shielded.

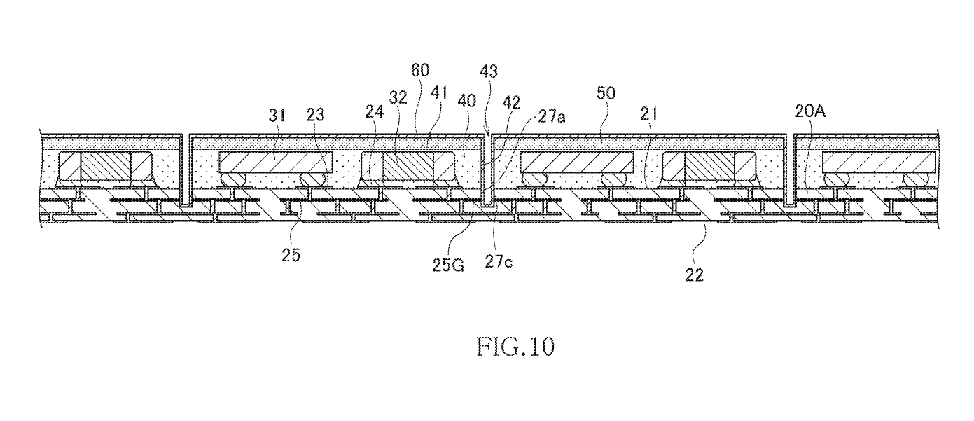

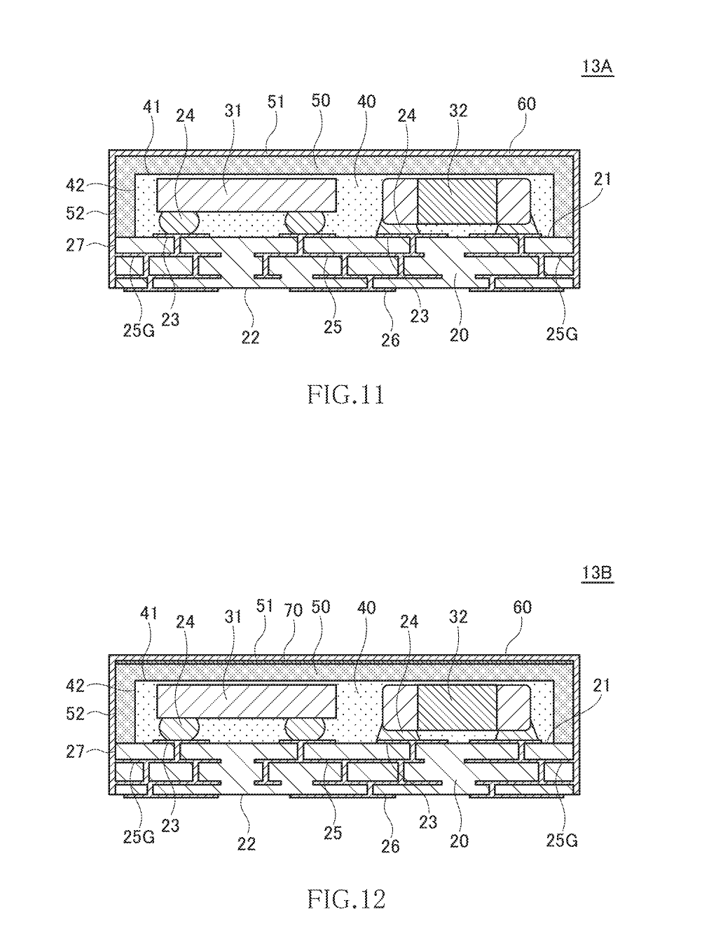

When a material having a comparatively low resistance value is used as the material for the magnetic film 50, the thin insulating film 70 is preferably interposed between the top surface 51 of the magnetic film 50 and the metal film 60 as in an electronic circuit package 13B of FIG. 12 according to a modification, and more preferably, the thin insulating film 70 is interposed between the top surface 51 and side surface 52 of the magnetic film 50 and the metal film 60 as in an electronic circuit package 13C of FIG. 13 according to another modification.

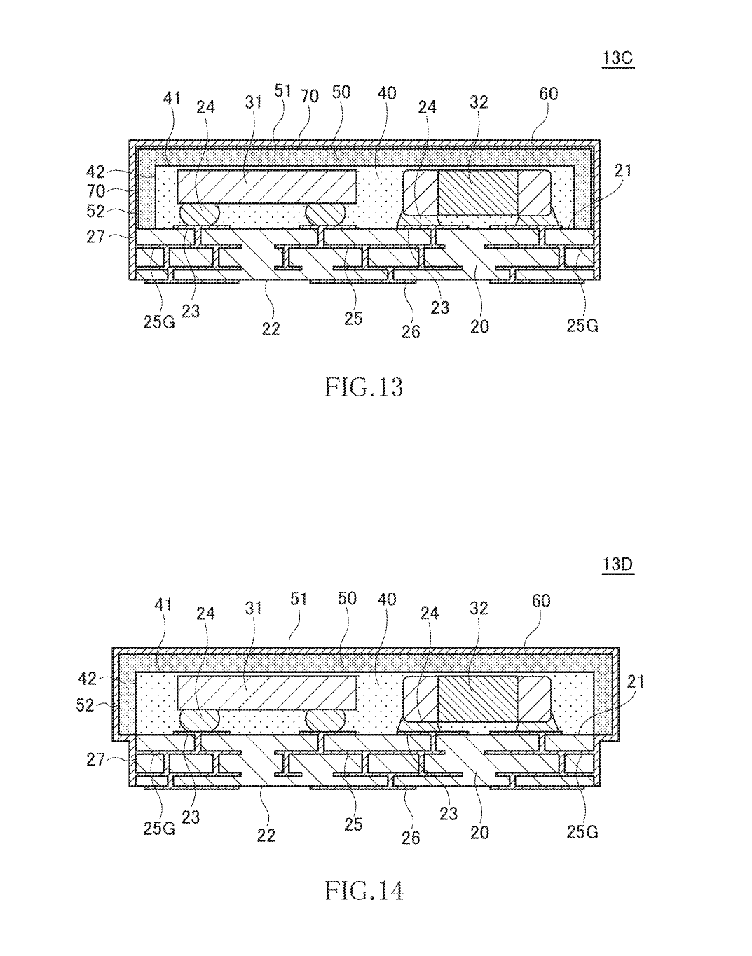

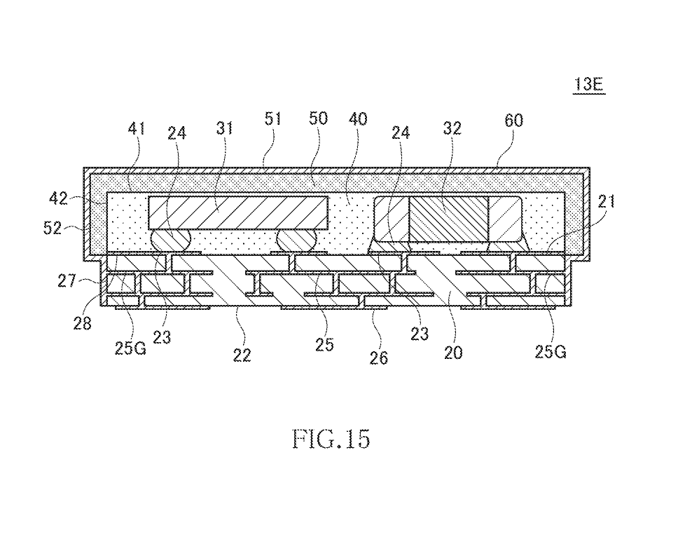

In the examples illustrated in FIGS. 11 to 13, the side surface 52 of the magnetic film 50 and the side surface 27 of the substrate 20 form substantially the same plane; however, it is not essential in the present invention. For example, as in an electronic circuit package 13D of FIG. 14 according to another modification, a configuration may be adopted, in which the side surface 42 of the mold resin 40 and the side surface 27 of the substrate 20 form the same plane and, at the same time, the side surface 42 of the mold resin 40 is covered by the magnetic film 50. Further, as in an electronic circuit package 13E of FIG. 15 according to another modification, a side surface of a wiring pattern 28 formed on the surface 21 of the substrate 20 may be covered with the magnetic film 50.

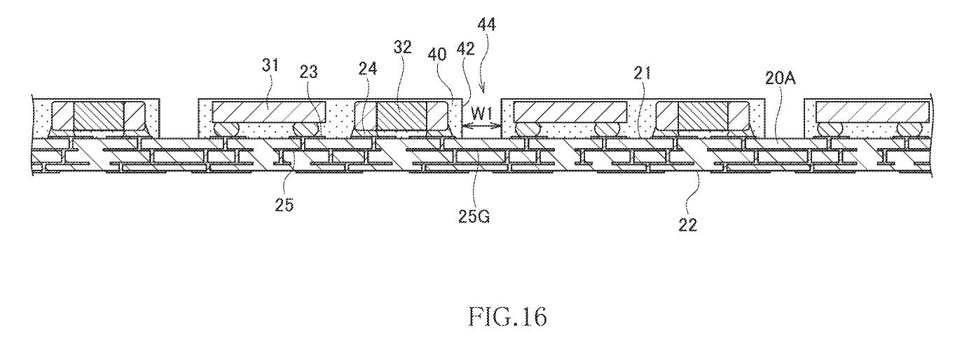

FIGS. 16 to 18 are process views for explaining a manufacturing method for the electronic circuit package 13A.

First, the mold resin 40 is formed by the method described using FIGS. 3 and 4. Then, as illustrated in FIG. 16, a groove 44 having a width W1 is formed along a dashed line a indicating a dicing position (See FIG. 3). The groove 44 has a depth almost completely cutting the mold resin 40 and not reaching the inner wiring 25 formed in the substrate 20. As a result, the side surface 42 of the mold resin 40 and the surface 21 of the substrate 20 are exposed inside the groove 44.

Then, as illustrated in FIG. 17, the magnetic film 50 is formed to fill the groove 44. Although it is not essential to completely fill the groove 44 with the magnetic film 50, when the groove 44 is filled with the magnetic film 50, the magnetic film needs to have a certain film thickness, so that it is necessary to use the composite magnetic material as the magnetic film 50. Thus, the magnetic film 50 is directly formed on the top surface 41 and side surface 42 of the mold resin 40, and the surface 21 of the substrate 20 exposed to the bottom of the groove 44 is also covered with the magnetic film 50. Further, as in the modification illustrated in FIG. 12, when the insulating film 70 is interposed between the top surface 51 of the magnetic film 50 and the metal film 60, after formation of the magnetic film 50, an insulating material such as a thermosetting material, a heat-resistant thermoplastic material, an Si oxide or a low-melting point glass may be thinly formed on the top surface 51 of the magnetic film 50.

Then, as illustrated in FIG. 18, a groove 45 having a width W2 is formed along the dashed line a to cut the assembly substrate 20A into a plurality of substrates 20. At this time, The width W2 of the groove 45 needs to be smaller than the width W1 of the groove 44. As a result, the substrate 20A is segmented into individual substrates 20 with the magnetic film 50 formed inside the groove 44 remaining. Further, as in the modification illustrated in FIG. 13, when the insulating film 70 is interposed between the top surface 51 and side surface 52 of the magnetic film 50 and the metal film 60, the side surface 52 of the magnetic film 50 is exposed by formation of the groove 45 without segmentation of the assembly substrate 20A, then an insulating material such as a thermosetting material, a heat-resistant thermoplastic material, an Si oxide or a low-melting point glass is thinly formed on the top surface 51 and side surface 52 of the magnetic film 50, followed by cutting of the assembly substrate 20A.

Then, the metal film 60 is formed so as to cover the top surface 51 and side surface 52 of the magnetic film 50 and the side surface 27 of the substrate 20, whereby the electronic circuit package 13A according to the present embodiment is completed.

As described above, in the manufacturing method for the electronic circuit package 13A according to the present embodiment, the two grooves 44 and 45 having different widths are sequentially formed, whereby the side surface 42 of the mold resin 40 can be covered with the magnetic film 50 without use of a complicated process.

### Fourth Embodiment

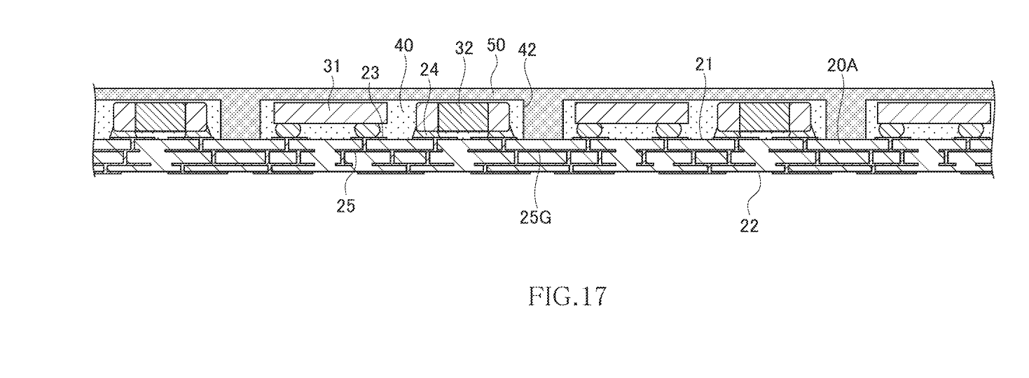

FIG. 19 is a cross-sectional view illustrating a configuration of an electronic circuit package 14A according to the fourth embodiment of the present invention.

As illustrated in FIG. 19, the electronic circuit package 14A according to the present embodiment has the same configuration as that of the electronic circuit package 13A of FIG. 11 according to the third embodiment except for shapes of the substrate 20 and metal film 60. Thus, in FIG. 19, the same reference numerals are given to the same elements as in FIG. 11, and repeated descriptions will be omitted.

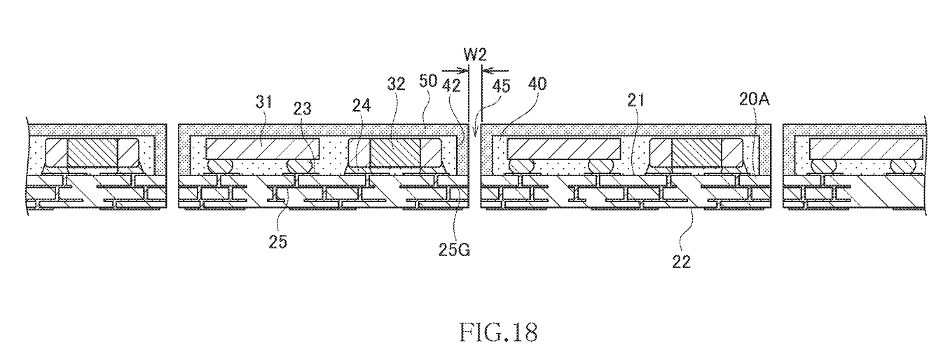

In the present embodiment, as in the second embodiment, the side surface lower portion 27b of the substrate 20 protrudes from the side surface upper portion 27a, and the metal film 60 is formed so as to cover the side surface upper portion 27a and step portion 27c. Also in the present embodiment, the power supply pattern 25G is exposed to the side surface upper portion 27a of the substrate 20, and the metal film 60 is connected to the power supply pattern 25G through the side surface upper portion 27a. When a material having a comparatively low resistance value is used as the material for the magnetic film 50, the thin insulating film 70 is preferably interposed between the top surface 51 (and side surface 52) of the magnetic film 50 and the metal film 60 as in an electronic circuit package 14B of FIG. 20 according to a modification.

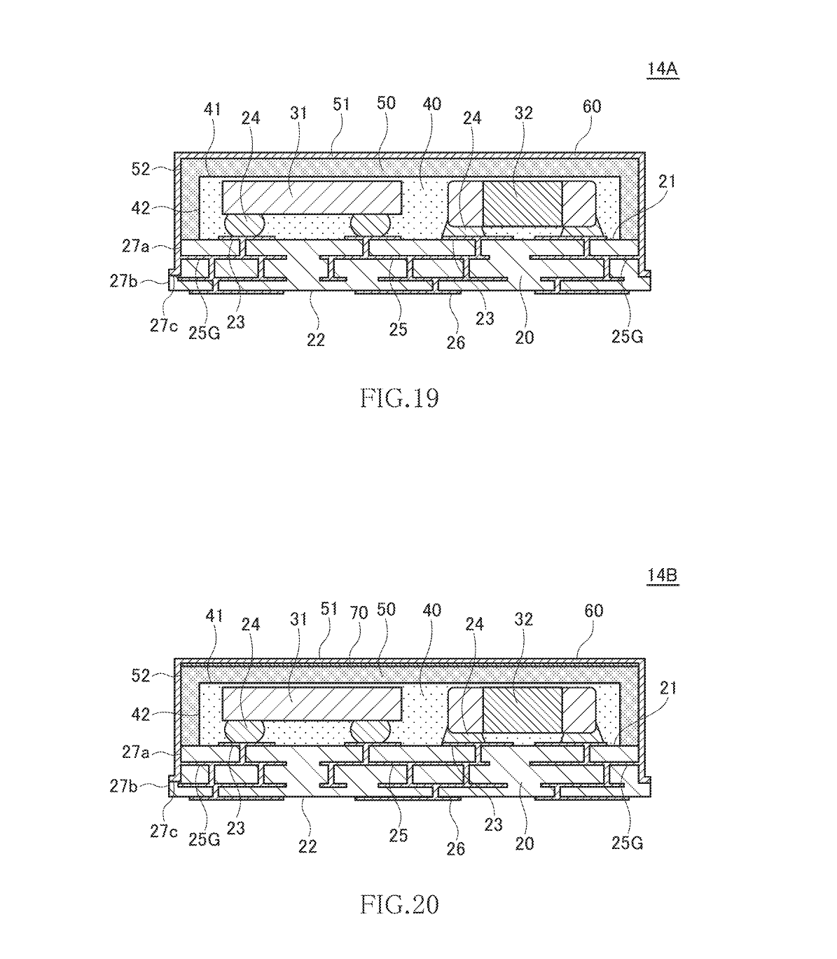

FIGS. 21 and 22 are process views for explaining a manufacturing method for the electronic circuit package 14A.

First, the magnetic film 50 is formed on the top surface 41 of the mold resin 40 and inside the groove 44 by the method described using FIGS. 3, 4, 16, and 17. Then, as illustrated in FIG. 21, a groove 46 having a width W3 is formed along the dashed line a indicating the dicing position (See FIG. 3). The groove 46 has a depth completely cutting the mold resin 40 and not completely cutting the substrate 20. The width W3 is made smaller than the width W1 of the groove 44 of FIG. 16. As a result, the side surface 52 of the magnetic film 50 and the side surface upper portion 27a and step portion 27c of the substrate 20 are exposed inside the groove 46. The depth of the side surface upper portion 27a needs to be set to at least a depth allowing the power supply pattern 25G to be exposed.

Then, as illustrated in FIG. 22, the metal film 60 is formed using a sputtering method, a vapor-deposition method, an electroless plating method, an electrolytic plating method, or the like. As a result, the top surface 51 of the magnetic film 50 and inside of the groove 46 are covered with the metal film 60. At this time, the power supply pattern 25G exposed to the side surface upper portion 27a of the substrate 20 is connected to the metal film 60.

Then, the assembly substrate 20A is cut along the dashed line a to segment the assembly substrate 20A into individual substrates 20, whereby the electronic circuit package 14A according to the present embodiment is completed.

As described above, according to the manufacturing method for the electronic circuit package 14A of the present embodiment, the metal film 60 can, similarly to the second embodiment, be formed before substrate segmentation, thereby facilitating formation of the metal film 60.

### Fifth Embodiment

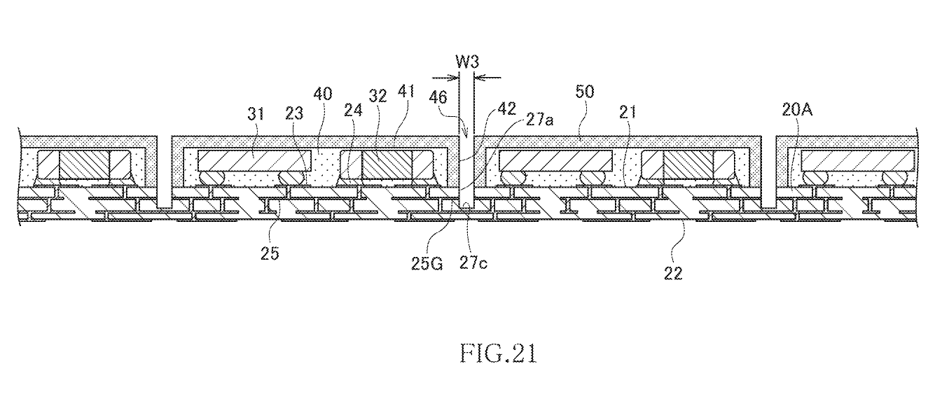

FIG. 23 is a cross-sectional view illustrating a configuration of an electronic circuit package 15A according to the fifth embodiment of the present invention.

As illustrated in FIG. 23, the electronic circuit package 15A according to the present embodiment differs from the electronic circuit package 13A of FIG. 11 according to the third embodiment in that the magnetic film 50 covers a part of the side surface 27 of the substrate 20. Other configurations are the same as those of the electronic circuit package 13A according to the third embodiment. Thus, in FIG. 23, the same reference numerals are given to the same elements as in FIG. 11, and repeated descriptions will be omitted.

In the present embodiment, the side surface 27 of the substrate 20 has a step shape. Specifically, a side surface lower portion 27e of the substrate 20 protrudes from a side surface upper portion 27d. The magnetic film 50 is formed so as to cover the top surface 41 and side surface 42 of the mold resin 40 and to further cover the side surface upper portion 27d and a step portion 27f of the substrate 20. The side surface lower portion 27e of the substrate 20 is not covered with the magnetic film 50, and the power supply pattern 25G exposed to the side surface lower portion 27e contacts the metal film 60.

With this configuration, an interface between the surface 21 of the substrate 20 and the mold resin 40 is covered with the magnetic film 50. In general, a solder resist is formed on the surface 21 of the substrate 20 and, when moisture contained in the substrate 20 or the mold resin 40 expands at the time of reflow, a peeling may occur between the substrate and solder resist or between the mold material and the solder resist, a crack may occur in the solder resist, mold material, or the substrate, and swelling, peeling, or the like may occur in the metal film 60 formed as an electromagnetic shield film. Further, the solder 24 that joins and fixes electronic components is melted around a MAX reflow temperature, so that a stress occurs due to volume expansion of the solder, which may accelerate the above phenomenon. However, in the present embodiment, the interface between the surface 21 of the substrate 20 and the mold resin 40 is retained by the magnetic film 50 with high adhesion, so that the above peeling is unlikely to occur. In particular, when the composite magnetic material is used as the material for the magnetic film 50, not only the interface between the substrate 20 and the mold resin 40 can be physically retained with high adhesion, but also moisture reaching the interface between the substrate 20 and the mold resin 40 can be moved through the composite magnetic material which is the material for the magnetic film 50. This can effectively prevent the peeling between the substrate and the solder resist or between the mold material and the solder resist, crack in the solder resist, mold material, or the substrate, and swelling, peeling, or the like in the metal film 60 formed as an electromagnetic shield film, thus increasing reliability.

The electronic circuit package 15A according to the present embodiment can be manufactured by forming the groove 44 more deeply in the process illustrated in FIG. 16.

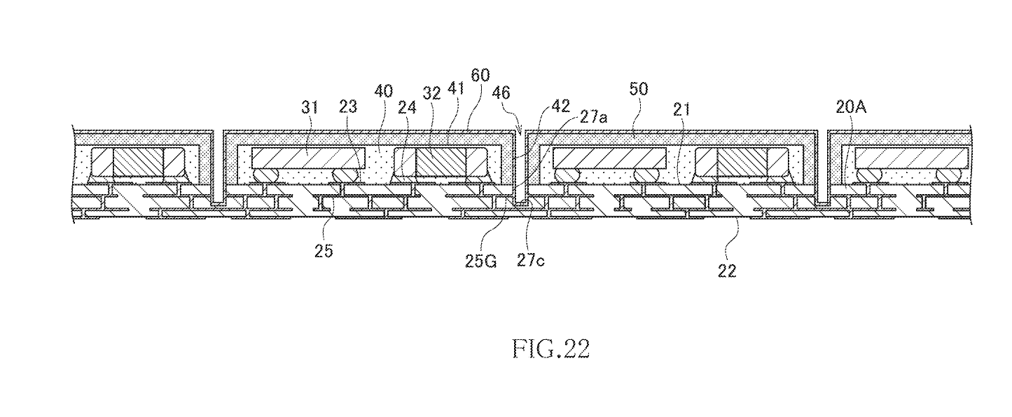

Also in the present embodiment, when a material having a comparatively low resistance value is used as the material for the magnetic film 50, the thin insulating film 70 is preferably interposed between the top surface 51 (and side surface 52) of the magnetic film 50 and the metal film 60 as in an electronic circuit package 15B of FIG. 24 according to a modification.

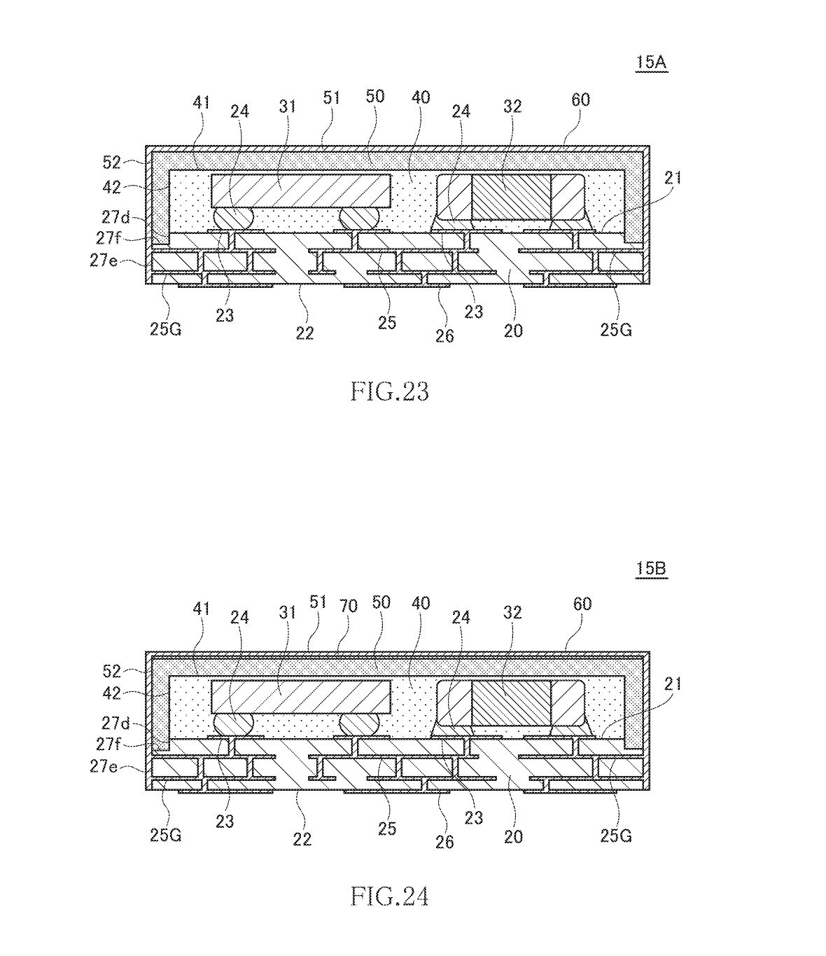

FIG. 25 is a cross-sectional view illustrating a configuration of an electronic circuit package 15C according to a modification.

The electronic circuit package 15C illustrated in FIG. 25 differs from the electronic circuit package 15A of FIG. 23 according to the fifth embodiment in that the magnetic film 50 covers a wiring pattern 29 exposed to the side surface 27 of the substrate 20. Other configurations are the same as those of the electronic circuit package 15A according to the fifth embodiment. Thus, in FIG. 25, the same reference numerals are given to the same elements as in FIG. 23, and repeated descriptions will be omitted.

The wiring pattern 29 contacting the magnetic film 50 may be a ground power supply pattern or a signal wiring. However, when a material having a high conductivity is used as the material for the magnetic film 50, the same potential as the power supply pattern 25G that the metal film 60 contacts needs to be applied to the wiring pattern 29.

With this configuration, it is possible to prevent not only the peeling between the substrate and the solder resist or between the mold material and the solder resist, crack in the solder resist, mold material, or the substrate, and swelling, peeling, or the like in the metal film 60 formed as an electromagnetic shield film, but also a peeling in the interface between the substrate 20 and the wiring pattern 29 due to expansion of the moisture, thus ensuring higher reliability. Also in this case, by using the composite magnetic material as the material for the magnetic film 50, peeling of the wiring pattern 29 can be prevented more effectively.

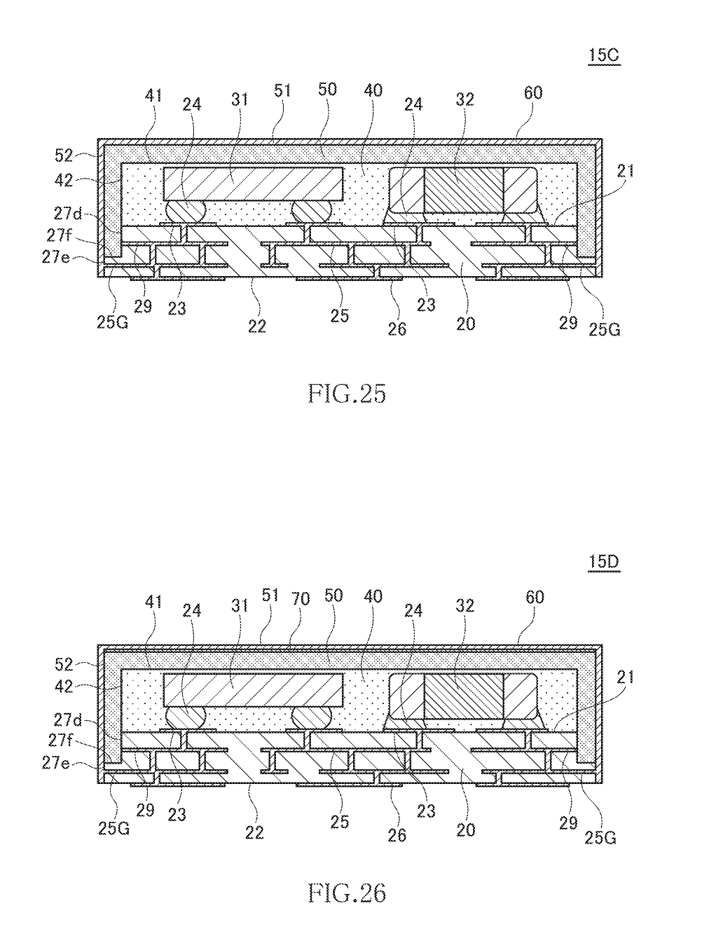

Also in the present embodiment, when a material having a comparatively low resistance value is used as the material for the magnetic film 50, the thin insulating film 70 is preferably interposed between the top surface 51 (and side surface 52) of the magnetic film 50 and the metal film 60 as in an electronic circuit package 15D of FIG. 26 according to a modification.

While the preferred embodiments of the present invention have been described, the present invention is not limited thereto. Thus, various modifications may be made without departing from the gist of the invention, and all of the modifications thereof are included in the scope of the present invention.

### EXAMPLES

An embodiment sample 1 having the same structure as that of the electronic circuit package 11A illustrated in FIG. 1 was actually produced. As the substrate 20, a multilayer resin substrate having a planar size of 8.5 mm×8.5 mm and a thickness of 0.3 mm was used. As the magnetic film 50, a composite magnetic material having a permeability μ=25 in which Fe-based spherical magnetic fillers are dispersed and mixed in a thermosetting resin was used. The magnetic film 50 was formed on the top surface 41 of the mold resin 40 by screen printing in a thickness of about 50 μm, followed by post-curing under predetermined conditions. As the metal film 60, a laminated film of Cu (having a film thickness of 1 μm) and Ni (having a film thickness of 2 μm) was used.

As a comparative example, comparative samples 1 and 2 were produced. The comparative sample 1 was obtained by removing the magnetic film 50 from the embodiment sample 1, and comparative sample 2 was obtained by removing the metal film 60 from the embodiment sample 1. Thus, as the shield, the comparative sample 1 only has an electromagnetic shield formed by the metal film 60, and the comparative sample 2 only has a magnetic shield formed by the magnetic film 50.

Then, each of the above samples was reflow mounted on a shield characteristic evaluation substrate, and a noise attenuation amount therein was measured by a neighboring magnetic field measuring apparatus to evaluate shield characteristics. The results are illustrated in Table 1. The unit of numeric values is dBμV.

TABLE 1

| | 100 MHz | 500 MHz |
|---|---|---|
| COMPARATIVE SAMPLE 1 (A) | 37.7 | 50.6 |
| COMPARATIVE SAMPLE 2 (B) | 4.2 | 3.1 |
| EMBODIMENT SAMPLE 1 (C) | 57.3 | 69.5 |
| SUM (A + B) | 41.9 | 53.8 |
| DIFFERENCE FROM SUM (C − (A + B)) | 15.4 | 15.7 |

Table 1 reveals that the embodiment sample 1 is larger in noise attenuation amount than the comparative samples 1 and 2 and further reveals that the noise attenuation amount of the embodiment sample 1 is larger than a sum (A+B) of the noise attenuation amount (A) of the comparative sample 1 having only the metal film 60 as the shield and noise attenuation amount (B) of the comparative sample 2 having only the magnetic film 50 as the shield. That is, a composite-shield having a structure in which the magnetic film 50 and metal film 60 are laminated in this order can obtain a higher composite-shield effect than in a case where a shield effect obtained by the electromagnetic shield formed only by the metal film 60 and a shield effect obtained by the magnetic field formed only by the magnetic film 50 are simply added to each other.

Then, another embodiment sample 2 having the same structure as that of the electronic circuit package 11A illustrated in FIG. 1 and a comparative sample 3 having a structure in which the lamination order of the magnetic film 50 and metal film 60 of the embodiment sample 2 is reversed were produced. Then, each of the above samples was mounted on a shield characteristic evaluation substrate, and a noise attenuation amount therein was measured by a neighboring magnetic field measuring apparatus. The results are illustrated in Table 2. The unit of numeric values is dBμV.

TABLE 2

| | 100 MHz | 500 MHz |
|---|---|---|
| COMPARATIVE SAMPLE 3 (D) | 47.3 | 64.6 |
| EMBODIMENT SAMPLE 2 (E) | 57.3 | 69.5 |
| DIFFERENCE (E − D) | 10.0 | 4.9 |

Table 2 reveals that the comparative sample 3 having a structure in which the lamination order of the magnetic film and metal film 60 is reversed is smaller in noise attenuation amount than the embodiment sample 2. This reveals that by laminating the magnetic film 50 and metal film 60 in this order, a high composite-shield effect can be obtained. Table 2 further reveals that a difference (E-D) between the embodiment sample 2 and the comparative sample 3 becomes more remarkable in a low-frequency region.

1. An electronic circuit package comprising:
a substrate having a power supply pattern;
an electronic component mounted on a surface of the substrate;
a mold resin covering the surface of the substrate so as to embed therein the electronic component;
a magnetic film formed so as to contact at least a top surface of the mold resin; and
a metal film electrically connected to the power supply pattern and covering the mold resin through the magnetic film,
wherein the magnetic film comprises one of an Fe—Co alloy, an Fe—Ni alloy, an Fe—Al alloy, an Fe—Si alloy, a ferrite film formed of NiZn, a ferrite film formed of MnZn, a ferrite film formed of NiCuZn, or Fe.

2. The electronic circuit package as claimed in claim 1, wherein the magnetic film further contacts a side surface of the mold resin.

3. The electronic circuit package as claimed in claim 2, wherein the magnetic film covers a part of a side surface of the substrate.

4. The electronic circuit package as claimed in claim 1, wherein the magnetic film comprises a composite magnetic material in which magnetic fillers are dispersed in a thermosetting resin material.

5. The electronic circuit package as claimed in claim 4, wherein the magnetic fillers are formed of a ferrite or a soft magnetic metal.

6. The electronic circuit package as claimed in claim 5, wherein a surface of the fillers is insulation-coated.

7. The electronic circuit package as claimed in claim 1, wherein the magnetic film comprises a thin film, a foil or a bulk sheet formed of a soft magnetic material or a ferrite.

8. The electronic circuit package as claimed in claim 1, wherein the metal film is mainly composed of at least one metal selected from a group consisting of Au, Ag, Cu, and Al.

9. The electronic circuit package as claimed in claim 1, wherein the metal film is covered with an antioxidant film.

10. The electronic circuit package as claimed in claim 1, wherein the power supply pattern is exposed to a side surface of the substrate, and the metal film contacts the power supply pattern exposed on the side surface of the substrate.

11. The electronic circuit package as claimed in claim 10, wherein the metal film covers a side surface of the magnetic film without an intervention of the mold resin.

12. An electronic circuit package comprising:
a substrate having a top surface;
an electronic component mounted on the top surface of the substrate;
a mold resin covering the top surface of the substrate so as to embed therein the electronic component;
a magnetic film covering the mold resin, the magnetic film having a top surface substantially parallel to the top surface of the substrate and a side surface substantially perpendicular to the top surface of the substrate; and
a metal film covering the top and side surfaces of the magnetic film without an intervention of the mold resin,
wherein the magnetic film comprises one of an Fe—Co alloy, an Fe—Ni alloy, an Fe—Al alloy, an Fe—Si alloy, a ferrite film formed of NiZn, a ferrite film formed of MnZn, a ferrite film formed of NiCuZn, or Fe.

13. The electronic circuit package as claimed in claim 12,
wherein the substrate further has a side surface substantially perpendicular to the top surface of the substrate and a power supply pattern, and
wherein the metal film electrically connected to the power supply pattern exposed on the side surface of the substrate.

14. The electronic circuit package as claimed in claim 13, wherein the mold resin has a top surface substantially parallel to the top surface of the substrate and a side surface substantially perpendicular to the top surface of the substrate.

15. The electronic circuit package as claimed in claim 14, wherein the metal film covers the side surface of the mold resin without an intervention of the magnetic film.

16. The electronic circuit package as claimed in claim 14, wherein the magnetic film covers the top and side surfaces of the mold resin.

17. The electronic circuit package as claimed in claim 16, wherein the magnetic film further covers the side surface of the substrate.

18. The electronic circuit package as claimed in claim 12, further comprising an insulating film interposed between the magnetic film and the metal film.

19. An electronic circuit package comprising:
a substrate having a power supply pattern;
an electronic component mounted on a surface of the substrate;
a mold resin covering the surface of the substrate so as to embed therein the electronic component;
a magnetic film formed so as to contact at least a top surface of the mold resin; and
a metal film electrically connected to the power supply pattern and covering the mold resin through the magnetic film,
wherein the magnetic film is greater in thickness than the metal film.

20. An electronic circuit package comprising:
a substrate having a top surface;
an electronic component mounted on the top surface of the substrate;
a mold resin covering the top surface of the substrate so as to embed therein the electronic component;
a magnetic film covering the mold resin, the magnetic film having a top surface substantially parallel to the top surface of the substrate and a side surface substantially perpendicular to the top surface of the substrate; and
a metal film covering the top and side surfaces of the magnetic film without an intervention of the mold resin,
wherein the magnetic film is greater in thickness than the metal film.
